(19) United States
(12) Patent Application Publication
(10) Pub. No.: US 2008/0224284 A1
(43) Pub. Date: Sep. 18, 2008

(54) CHIP PACKAGE STRUCTURE

(75) Inventors: Yan-Yi Wu, Shanghai (CN); Yong-Chao Qiao, Shanghai (CN); Jie-Hung Chiou, Shanghai (CN)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: CHIPMOS TECHNOLOGIES (BERMUDA) LTD., Hamilton (BM)

(21) Appl. No.: 11/739,696

(22) Filed: Apr. 25, 2007

(30) Foreign Application Priority Data
Mar. 13, 2007 (CN) 200710087673.5

(51) Int. Cl. H01L 23/495; H01L 23/48

(52) U.S. Cl. 257/673; 257/778; 257/E23.01

(57) ABSTRACT

A chip package structure mainly including a substrate, a chip and a lead frame is provided. The chip is disposed on the substrate, and is electrically connected to the chip by flip-chip or wire-bonding technique. The chip is electrically connected to the lead frame through a redistribution layer on the substrate. Therefore, a problem that the bonding wires may collapse due to a longer distance between the chip and the lead frame may be resolved, thus improving the yield rate thereof.

### CROSS-REFERENCE TO RELATED APPLICATION

This application claims the priority benefit of P.R.C. application serial no. 200710087673.5, filed Mar. 13, 2007. All disclosure of the P.R.C. application is incorporated herein by reference.

### BACKSIDEGROUND OF THE INVENTION

1. Field of the Invention

The present invention generally relates to a semiconductor element and a method of manufacturing the same, and more particularly, to a chip package structure and a method of manufacturing the same.

2. Description of Related Art

In semiconductor industry, production of integrated circuit (IC) is mainly divided into three stages: IC design, IC process and IC package. In IC process, a die is obtained after wafer process, IC forming and wafer sawing, etc. A wafer has an active surface that generally refers to a surface having active device. After completion of IC of the wafer, bonding pads are disposed on the active surface of the wafer so that a chip sawed from the wafer can be connected to a carrier via these bonding pads. The carrier may be a lead frame or a package substrate, and the chip may be connected to the carrier by wire bonding or flip chip bonding. In such a way, the bonding pads of the chip are electrically connected to leads of the carrier to form a chip package.

As wire bonding technique is concerned, a chip package with a small number of leads mainly uses a package technique with the lead frame as a main body. After major steps of wafer sawing, die bonding, wire bonding, molding and trimming/forming, etc., a chip package with a lead frame as main body in the prior art is substantially finished.

With a trend that current electronic products are seeking to be lighter, smaller and thinner, there is also a tendency to reduce the size of chips. With the size of a chip being reduced, the distance between the chip and inner leads of a lead frame is increased, which leads to that the length of a bonding wire for electrically connecting the chip with the inner lead of the lead frame has to be increased. However, when the length and radian of the bonding wire are increased, a short circuit easily happens to the bonding wire due to collapse, and the bonding wire is easily broken off due to infused resin during molding, which results in an open circuit. The yield rate of chip packages is therefore reduced. However, it will increase cost if refabricating a mold to manufacture lead frames adapted to miniaturized chips.

### SUMMARY OF THE INVENTION

Accordingly, the present invention is directed to a chip package structure, wherein the chip package structure comprises a chip being disposed on a substrate and electrically connected to the substrate. A redistribution layer is disposed on the substrate so that the chip is capable of being electrically connected to a lead frame via the redistribution layer, thereby resolving a problem that the yield rate is reduced or that manufacturing cost is increased when packaging a miniaturized chip by using a lead frame.

According to an embodiment of the present invention, a chip package structure is provided. The chip package structure comprises a substrate, a chip, a plurality of bonding wires and a lead frame. The substrate has a surface having a redistribution layer, and the redistribution layer has a plurality of redistribution conductive traces. Each of the redistribution conductive traces has a first end and a corresponding second end. The chip has an active surface, a back surface and a plurality of bonding pads disposed on the active surface, wherein the back surface of the chip is fixed to the surface of the substrate. The bonding wires are electrically connected to the bonding pads and first ends of the redistribution conductive traces respectively. The lead frame comprises a plurality of leads disposed on the surface of the substrate, and at least a portion of the leads are electrically connected to the second ends of the corresponding redistribution conductive traces, respectively.

According to an embodiment of the present invention, each of the leads has an inner lead, respectively, and these inner leads are disposed outside the chip.

According to an embodiment of the present invention, at least a portion of the inner leads are electrically connected to the second ends of the corresponding redistribution conductive traces, respectively.

According to an embodiment of the present invention, the redistribution layer further comprises a plurality of first pads and second pads, wherein the first pads are disposed on the first ends of the corresponding redistribution conductive traces, respectively, and the second pads are disposed on the second ends of the corresponding redistribution conductive traces, respectively.

According to an embodiment of the present invention, the bonding wires are electrically connected to the bonding pads and the first pads, respectively.

According to an embodiment of the present invention, the substrate further comprises a plurality of conductive layers disposed on the second pads respectively, such that the redistribution layer of the substrate is electrically connected to the inner leads via these conductive layers.

According to an embodiment of the present invention, each of the conductive layers comprises a conductive adhesive or a conductive bump.

According to an embodiment of the present invention, the conductive adhesive comprises silver epoxy, an anisotropic conductive adhesive, an anisotropic conductive film or a conductive B-stage adhesive.

According to an embodiment of the present invention, the material of the conductive bump comprises soldering material, gold, copper, nickel, aluminium or conductive B-stage material.

In an embodiment of the present invention, the chip package structure further comprises an encapsulant covering the chip, the bonding wires, the leads and at least part of the substrate.

In addition to wire bonding techniques, the chip may be electrically connected to the substrate by flow chip bonding techniques. The structure is similar to that described above with only difference in the way of connecting the chip with the substrate, and thus, a description is omitted.

In a chip package structure according to the present invention, a miniaturized chip is firstly disposed on a substrate and electrically connected to the substrate, and then electrically connected to a lead frame through a redistribution layer on the substrate. In the prior art, because the length of the bonding wires for electrically connecting the chip and inner leads of the lead frame has to be increased when the size of the chip is reduced, there is a problem that bonding wires easy collapse or that the bonding wires are easily broken off due to infused resin during molding, which results in an open circuit. According to the present invention, the problem can be avoided, thereby improving the yield rate of manufacturing. In addition, since the locations of the pads are redistributed according to the bonding manner by using a redistribution layer, therefore, it is applicable for a lead frame with a large number of leads.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view of a chip package structure according to an embodiment of the present invention.

FIG. 1B is a cross-section view of the chip package structure as shown in FIG. 1A along a line I-I′.

FIG. 2 is a cross-section view of a chip package structure according to another embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

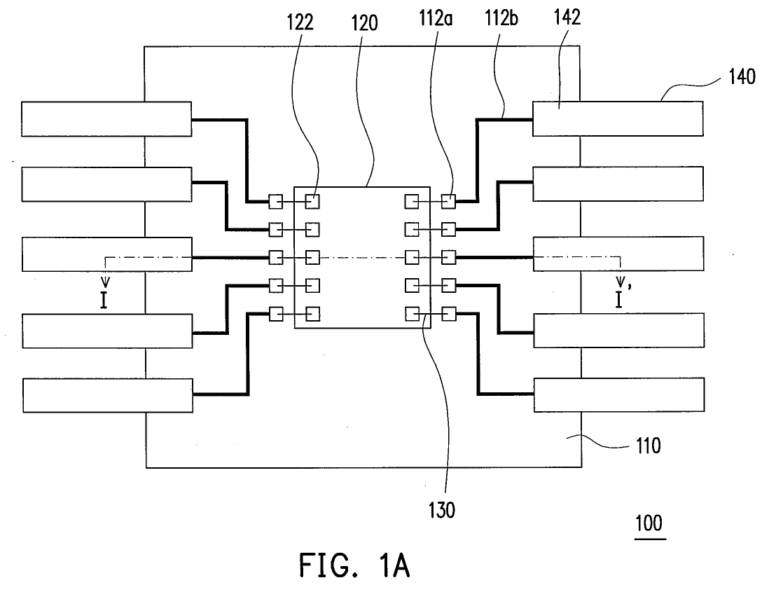

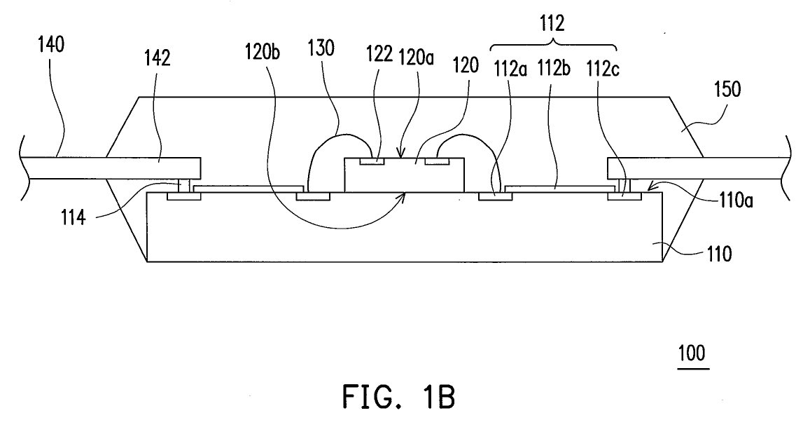

FIG. 1A is a top view of a chip package structure according to an embodiment of the present invention, and FIG. 1B is a cross-section view of the chip package structure as shown in FIG. 1A along a line I-I′. Referring to FIGS. 1A and 1B, the chip package 100 generally includes a substrate 110, a chip 120, a plurality of bonding wires 130, and a lead frame (not shown) having a plurality of leads 140. An upper surface 110a of the substrate has a redistribution layer 112, and the redistribution layer 112 has a plurality of first pads 112a, a plurality of redistribution conductive traces 112b, and a plurality of second pads 112c. The first pad 112a and the second pad 112c are disposed on corresponding ends of the redistribution wire 112b.

The chip 120 has an active surface 120a, a back surface 120b and a plurality of bonding pads 122 disposed on the active surface 120a. The back surface 120b of the chip 120 may be fixed to the upper surface 110a of the substrate 10 by adhesive material (not shown in the figures). A plurality of bonding wires 130 formed by wire-bonding technique are electrically connected to the bonding pads 122 of the chip 120 and the first pads 112a of the redistribution layer 112 respectively, such that the chip 120 is electrically connected to the substrate 110 through the bonding wires 130.

The leads 140 are disposed on the upper surface 110a of the substrate 110, and each lead 140 comprises an inner lead 142 outside the chip 120. These inner leads 142 are electrically connected to the second pads 112c of the redistribution layer 112, respectively, i.e., it may be that at least some of these inner leads 142 are electrically connected to the second pads 112c of the redistribution layer 112, respectively. Accordingly, the bonding pads 122 of the chip 120 are electrically connected to the inner leads 142 respectively via the bonding wires 130 and the redistribution layer 112. In this embodiment, the leads 140 are electrically connected to the second pads 112c respectively through conductive layers 114 disposed on the second pads 112c of the substrate 110. More specifically, the conductive layers 114 may be conductive bumps, conductive adhesives or a combination thereof. Wherein, the material of the conductive bump may be soldering material, gold, copper, nickel, aluminium or conductive B-stage material. The conductive adhesives may be silver epoxy, anisotropic conductive adhesives, anisotropic conductive films or conductive B-stage adhesives. However the leads 140 may also be electrically connected to the substrate 110 in other ways, such as by wire bonding. The method for electrically connecting the leads 140 and the substrate 110 is not limited in the present invention.

In addition, the chip package structure 100 further includes an encapsulant 150 covering the chip 120, the bonding wires 130, the leads 140, and at least part of the substrate 110 to protect the substrate 110, the chip 120, the boding wires 130, and the leads 140 from being damaged or affected with damp. In other embodiments not shown, the encapsulant 150 may also entirely cover the substrate 110.

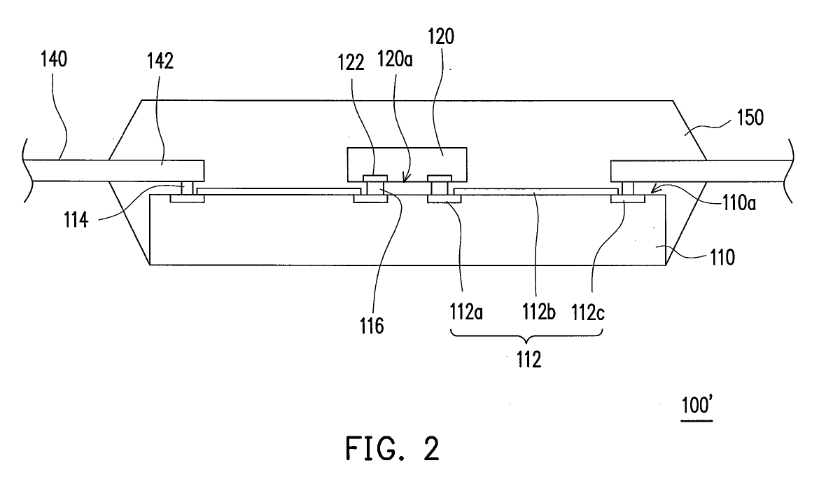

FIG. 2 is a cross-section view of a chip package structure according to another embodiment of the present invention. Referring to FIG. 2, the chip package structure 100′ is substantially similar to the chip package structure 100 shown in FIG. 1, but with differences in that a chip 120 is electrically connected to a substrate 110 by flip-chip-bonding technique, and the chip 120 is electrically connected to the substrate 110 through conductive bumps 116 disposed on first pads 112a in this embodiment. The material of the conductive bumps 116 according to this embodiment may be soldering material, gold, copper, nickel, aluminium or conductive B-stage material. Other elements of the chip package structure 100′ are the same to those shown in FIG. 1B, and thus, a description thereof will be omitted.

As descried above, in a chip package structure according to the present invention, a miniaturized chip is firstly disposed on a substrate and electrically connected to the substrate, and then electrically connected to a lead frame through a redistribution layer on the substrate. In the prior art, because the length of the bonding wires for electrically connecting the chip and inner leads of the lead frame has to be increased when the size of the chip is reduced, there is a problem that bonding wires easy collapse or that the bonding wires are easily broken off due to infused resin during molding, which results in an open circuit. According to the present invention, the problem can be avoided, thereby improving the yield rate of manufacturing. In addition, according to the present invention, locations of pads are redistributed according to the bonding manner by using a redistribution layer, therefore, it is applicable for a lead frame with a large number of leads.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip package structure, comprising:
a substrate, a surface thereof having a redistribution layer, wherein the redistribution layer has a plurality of redistribution conductive traces, and each of the redistribution conductive traces has a first end and a corresponding second end;
a chip having an active surface, a back surface and a plurality of bonding pads disposed on the active surface, the back surface of the chip being fixed to the surface of the substrate;
a plurality of bonding wires electrically connected to the bonding pads and the first ends of the redistribution conductive traces, respectively; and
a lead frame comprising a plurality of leads disposed on the surface of the substrate, wherein at least a portion of the leads are electrically connected to the second ends of the corresponding redistribution conductive traces, respectively.

2. The chip package structure according to claim 1, wherein each of the leads has an inner lead, respectively, and the inner leads are disposed outside of the chip.

3. The chip package structure according to claim 2, wherein at least a portion of the inner leads are electrically connected to the second ends of the corresponding redistribution conductive traces, respectively.

4. The chip package structure according to claim 1, wherein the redistribution layer further comprises a plurality of first pads and a plurality of second pads, each of the first pads being disposed on the first end of the corresponding redistribution conductive trace, and each of the second pad being disposed on the second end of the corresponding redistribution conductive trace.

5. The chip package structure according to claim 4, wherein the bonding wires are electrically connected to the bonding pads and the first pads, respectively.

6. The chip package structure according to claim 4, wherein the substrate further comprises a plurality of conductive layers disposed on the second pads, respectively, such that the redistribution layer of the substrate is electrically connected to the inner leads via the conductive layers.

7. The chip package structure according to claim 6, wherein each of the conductive layers comprises a conductive adhesive or a conductive bump.

8. The chip package structure according to claim 7, wherein the conductive adhesive comprises silver epoxy, an anisotropic conductive adhesive, an anisotropic conductive film or a conductive B-stage adhesive.

9. The chip package structure according to claim 7, wherein the material of the conductive bump comprises soldering material, gold, copper, nickel, aluminium or conductive B-stage material.

10. The chip package structure according to claim 1, further comprises an encapsulant covering the chip, the bonding wires, the leads and at least part of the substrate.

11. A chip package structure, comprising:
a substrate, a surface thereof having a redistribution layer, wherein the redistribution layer has a plurality of redistribution conductive traces, and each of the redistribution conductive traces has a first end and a corresponding second end;
a chip having an active surface, a back surface and a plurality of conductive bumps disposed on the active surface, wherein the conductive bumps are electrically connected to the first ends of the redistribution conductive traces, respectively; and
a lead frame comprising a plurality of leads disposed on the surface of the substrate, wherein each of the leads has an inner lead, and the inner leads are electrically connected to the second ends of the redistribution conductive traces, respectively.

12. The chip package structure according to claim 11, wherein the redistribution layer further comprises a plurality of first pads and second pads, the first pads being disposed on the first ends of the corresponding redistribution conductive traces, respectively, and the second pads being disposed on the second ends of the corresponding redistribution conductive traces, respectively.

13. The chip package structure according to claim 11, wherein the conductive bumps are electrically connected to the first pads, respectively, by flow chip bonding.

14. The chip package structure according to claim 11, wherein the material of the conductive bump comprises soldering material, gold, copper, nickel, aluminium or conductive B-stage material.

15. The chip package structure according to claim 11, wherein the substrate further comprises a plurality of conductive layers disposed on the second pads respectively, such that the redistribution layer of the substrate is electrically connected to the inner leads via the conductive layers.

16. The chip package structure according to claim 15, wherein each of the conductive layers is a conductive adhesive or a conductive bump.

17. The chip package structure according to claim 16, wherein the conductive adhesive comprises silver epoxy, an anisotropic conductive adhesive, an anisotropic conductive film or a conductive B-stage adhesive.

18. The chip package structure according to claim 16, wherein the material of the conductive bump comprises soldering material, gold, copper, nickel, aluminium or conductive B-stage material.

19. The chip package structure according to claim 11, further comprises an encapsulant covering the chip, the bonding wires, the leads, and at least part of the substrate.
